(19) United States
(12) Patent Application Publication
(10) Pub. No.: US 2025/0364240 A1
(43) Pub. Date: Nov. 27, 2025

(54) METHOD FOR PROCESSING WORKPIECES, PROCESSING APPARATUS, AND METHOD FOR MANUFACTURING A WAFER

(71) Applicant: DISCO CORPORATION, Tokyo (JP)

(72) Inventors: Maho HIRAKAWA, Tokyo (JP); Kazuya HIRATA, Tokyo (JP)

(73) Assignee: DISCO CORPORATION, Tokyo (JP)

(21) Appl. No.: 19/213,199

(22) Filed: May 20, 2025

(30) Foreign Application Priority Data
May 24, 2024 (JP) 2024-084472
Oct. 24, 2024 (JP) 2024-187759

(51) Int. Cl. H01L 21/02; B24B 37/04; B24B 37/30

(52) U.S. Cl. CPC H01L 21/02013; B24B 37/042; B24B 37/30

(57) ABSTRACT

A method for processing workpieces includes holding a first workpiece on a first holder device and holding a second workpiece made of a same material as the first workpiece on a second holder device, reducing roughness of the first workpiece and the second workpiece including moving the first workpiece and the second workpiece relatively while the first workpiece and the second workpiece are maintained in contact with each other to reduce roughness on contacting surfaces of the first workpiece and the second workpiece that contact each other, and supplying a polishing liquid to a contact area between the first workpiece and the second workpiece.

### CROSS REFERENCE TO RELATED APPLICATION

This application is based upon and claims the benefit of priority from the prior Japanese Patent Application No. 2024-084472 filed on May 24, 2024 and the prior Japanese Patent Application No. 2024-187759 filed on Oct. 24, 2024; the entire contents of which are incorporated herein by reference.

### FIELD

The present disclosure relates a method for processing workpieces, a processing apparatus, and a method for manufacturing a wafer.

### BACKGROUND

Conventionally, in order to reduce roughness on a surface of a workpiece, a processing tool such as a grinding wheel or a polishing pad may be used to reduce the roughness and flatten the workpiece (see, for example, Japanese Patent Application Laid-Open Publications No. 2019-029382, No. 2019-161037, and No. 2022-025566). However, depending on a material of the workpiece, it may be difficult to reduce the roughness using the above-mentioned processing tool. Based on such difficulty, a method for reducing roughness is suggested in Japanese Patent Application Laid-Open Publication No. 2023-116242.

According to the method for reducing roughness disclosed in Publication No. 2023-116242, by moving workpieces of a same material that are placed in contact with each other relatively to rub each other, roughness on the contacting surfaces of the workpieces may be reduced regardless of the material of the workpieces. Meanwhile, further improvement of the method for reducing roughness in workpieces is expected.

### SUMMARY

In view of the above, the present disclosure is aimed at providing a method for processing workpieces, a processing apparatus, and a method for manufacturing a wafer that may efficiently reduce roughness of the workpieces.

According to an aspect of the present disclosure, a method for processing workpieces includes holding a first workpiece on a first holder device and holding a second workpiece made of a same material as the first workpiece on a second holder device, reducing roughness of the first workpiece and the second workpiece including moving the first workpiece and the second workpiece relatively while the first workpiece and the second workpiece are maintained in contact with each other to reduce roughness on contacting surfaces of the first workpiece and the second workpiece that contact each other, and supplying a polishing liquid to a contact area between the first workpiece and the second workpiece.

According to another aspect of the present disclosure, a processing apparatus includes a first holder device configured to hold a first workpiece, a second holder device configured to hold a second workpiece made of a same material as the first workpiece in an arrangement such that the second workpiece faces the first workpiece held on the first holder device, a motion device configured to move the first holder device and the second holder device relatively, and a polishing liquid supply unit configured to supply a polishing liquid to a contact area between the first workpiece and the second workpiece. The processing apparatus is configured to reduce roughness on surfaces of the first workpiece and the second workpiece that contact each other by operating the polishing liquid supply unit to supply the polishing liquid to the contact area between the first workpiece and the second workpiece, and operating the motion device to move the first workpiece held on the first holder and the second workpiece held on the second holder device relatively while the first workpiece and the second workpiece are maintained in contact with each other.

According to another aspect of the present disclosure, a method for manufacturing a wafer from at least one of a first workpiece or a second workpiece made of a same material as the first workpiece includes holding the first workpiece on a first holder device and holding the second workpiece on a second holder device, reducing roughness of the first workpiece and the second workpiece including moving the first workpiece and the second workpiece relatively while the first workpiece and the second workpiece are maintained in contact with each other to reduce roughness on contacting surfaces of the first workpiece and the second workpiece that contact each other, and supplying a polishing liquid to a contact area between the first workpiece and the second workpiece.

According to the present disclosure, roughness on workpieces may be reduced efficiently.

### BRIEF DESCRIPTION OF THE DRAWINGS

FIG. 1 is an illustrative side view of a processing apparatus according to a first embodiment.

FIG. 2 is a flowchart of step included in a method for processing workpieces to be performed in the processing apparatus according to the first embodiment.

FIG. 3A is a sideward view of a cutting apparatus to illustrate a separable layer forming step in the processing method according to the first embodiment.

FIG. 3B is a perspective view of the cutting apparatus to illustrate the separable layer forming step in the processing method according to the first embodiment.

FIG. 4 is a perspective view of the cutting apparatus to illustrate a separating step in the processing method according to the first embodiment.

FIG. 5 is a side view of workpieces being in a state shortly after a roughness reducing step started in the processing method according to the first embodiment.

FIG. 6 is a side view of the workpieces being in a state shortly before the roughness reducing step ends in the processing method according to the first embodiment.

FIG. 7 is a perspective view of a grinding apparatus to illustrate a grinding step in the processing method according to the first embodiment.

FIG. 8 is another perspective view of the grinding apparatus to illustrate the grinding step in the processing method according to the first embodiment.

FIG. 9 is an illustrative side view of a processing apparatus according to a second embodiment.

FIG. 10 is an overall illustrative view of a processing apparatus performing a debris utilizing step in a processing method according to a third embodiment.

FIG. 11 is another overall illustrative view of the processing apparatus performing the debris utilizing step in the processing method according to the third embodiment.

FIG. 12 is another overall illustrative view of the processing apparatus performing the debris utilizing step in the processing method according to the third embodiment.

### DESCRIPTION OF EMBODIMENTS

With reference to the accompanying drawings, a method for processing workpieces, a processing apparatus, and a method for manufacturing a wafer according to embodiments of the present disclosure will be described. According to the method for processing workpieces, the processing apparatus, and the method for manufacturing a wafer in the embodiments of the present disclosure, by moving a first workpiece and a second workpiece that are made of the same material and are in contact with each other relatively, roughness on contacting surfaces of the first and the second workpieces may be reduced. In particular, by supplying a polishing liquid to a contact area between the first workpiece and the second workpiece, the roughness may be reduced efficiently. The embodiments will be described hereinbelow.

### First Embodiment

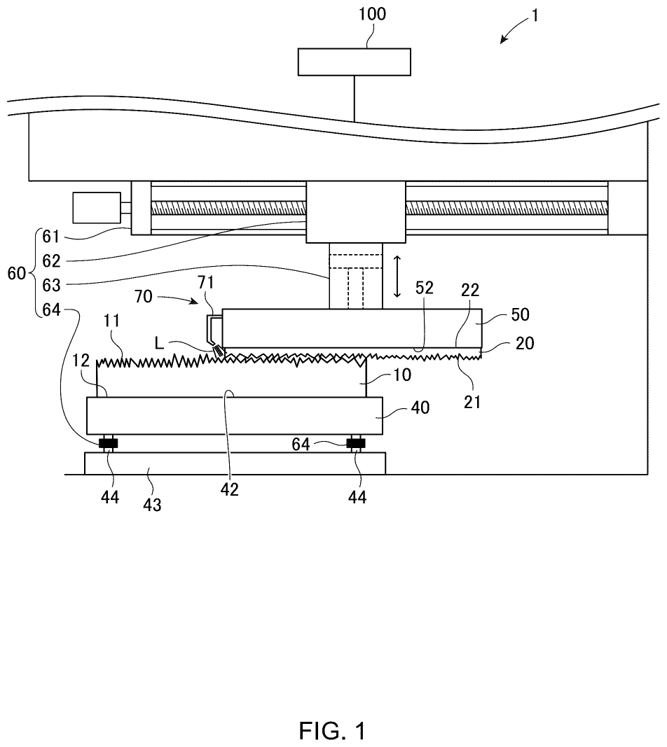

FIG. 1 is an illustrative side view of a processing apparatus 1 according to a first embodiment. First, a configuration of the processing apparatus 1 will be described with reference to FIG. 1. The processing apparatus 1 shown in FIG. 1 is usable in the processing method according to the embodiment of the present disclosure. The processing apparatus 1 includes a first holder device 40, a second holder device 50, a motion unit 60, a polishing liquid supply unit 70, and a control unit 100. The processing apparatus 1 may, using a workpiece 10 and a workpiece 20 that are made of a same material, reduce roughness of a surface 11, which is a processing target, of the workpiece 10 and roughness of a surface 21, which is another processing target, of the workpiece 20.

The first holder device 40 is configured to hold the workpiece 10 being the first workpiece. The first holder device 40 includes a flat holder surface 42 connected to a suction source, which is not shown. When the unshown suction source operates, a suction force acts on the holder surface 42, thereby suctioning a surface 12, which is a surface opposite to the surface 11 being the process target, of the workpiece 10 to hold the workpiece 10 on the holder surface 42. The first holder device 40 is fixed to a mounting base 43 via support columns 44 in a posture such that the holder surface 42 faces upward and stays substantially horizontally.

The second holder device 50 is configured to hold the workpiece 20 being the second workpiece in an arrangement such that the workpiece 20 faces the workpiece 10 held on the first holder device 40. The second holder device 50 is located above the first holder device 40 and includes a flat holder surface 52 connected to a suction source, which is not shown. When the unshown suction source operates, a suction force acts on the holder surface 52, thereby suctioning a surface 22, which is a surface opposite to the surface 21 being the process target, of the workpiece 20 to hold the workpiece 20 on the holder surface 52. The second holder device 50 is supported by the motion unit 60 in a posture such that the holder surface 52 faces downward and stays substantially horizontally.

The motion unit 60 is a mechanism to move the first holder device 40 and the second holder device 50 relatively. In the present embodiment, the motion unit 60 configured to move the second holder device 50 is described as an example of the motion unit. Alternatively, the motion unit 60 may be configured to move the first holder device 40 rather than the second holder device 50, thereby relatively moving the second holder device 50 with respect to the first holder device 40. Optionally, the motion unit 60 may be configured to move both the first holder device 40 and the second holder device 50. The motion unit 60 includes a first motion unit 61, a table 62, a second motion unit 63, and pressure sensors 64.

The first motion unit 61 is configured to move the second holder device 50 in a horizontal direction, which is parallel to the holder surface 52. The second motion unit 63 is configured to move the second holder device 50 in a vertical direction, which is perpendicular to the holder surface 52. The first motion unit 61 and the second motion unit 63 are connected via the table 62, and the second holder device 50 is attached to a tip end of the second motion unit 63.

As the first motion unit 61 moves the table 62 in the horizontal direction, the second holder device 50 connected to the table 62 via the second motion unit 63 moves in the horizontal direction. The first motion unit 61 may move the second holder device 50 at least between a closer position, where the holder surface 52 of the second holder device 50 faces the holder surface 42 of the first holder device 40 in the vertical direction, and a retracted position, where the holder surface 52 of the second holder device 50 is withdrawn from the position above the holder surface 42 of the first holder device 40.

As the second motion unit 63 moves in the vertical direction, the second holder device 50 attached to the tip end thereof moves vertically. More specifically, when the second motion unit 63 moves downward, the second holder device 50 approaches the first holder device 40, and when the second motion unit 63 moves upward, the second holder device 50 and the first holder device 40 are separated.

The configurations of the first motion unit 61 and the second motion unit 63 are not necessarily limited as long as the first motion unit 61 and the second motion unit 63 are each movable to reciprocate linearly. The first motion unit 61 and the second motion unit 63 each may be, for example, a known linear actuator including a linear guide, a ball screw, and a motor.

The pressure sensors 64 are respectively attached to the support columns 44 that support the first holder device 40 on the mounting base 43. The pressure sensors 64 may each be composed of, for example, a known strain gauge and may measure a pressure generated when the workpiece 20 held by the second holder device 50 is pressed against the workpiece 10 held on the first holder device 40. Measurement values obtained by the pressure sensors 64 are transmitted to the control unit 100.

The arrangement of the pressure sensors 64 is not necessarily limited to the above example. In the present embodiment, the pressure sensors 64 are arranged between the first holder device 40 and the mounting base 43. However, as long as the pressing force generated between the workpiece 10 and the workpiece 20 is measurable, the pressure sensors 64 may be arranged elsewhere, such as in the second holder device 50.

The polishing liquid supply unit 70 is a unit that may supply a polishing liquid L to a contact area between the workpiece 10 and the workpiece 20. The polishing liquid supply unit 70 includes a nozzle 71 fixed to a side of the second holder device 50 and is configured to supply the polishing liquid L to the contact area through the nozzle 71. The polishing liquid L may be any liquid that promotes reduction of roughness of the surfaces, such as a CMP slurry usable in chemical mechanical polishing.

The control unit 100 includes a processing unit, which may generate signals for controlling various components of the processing apparatus 1, and a storage, which may store various types of information to be used by the processing unit. The processing unit includes a processor such as a CPU, which may read and execute programs stored in the storage to control the operations of the various components in the processing apparatus 1. The processing apparatus 1 may perform the method for processing workpieces, which will be described in detail below, by running the programs with the processing unit.

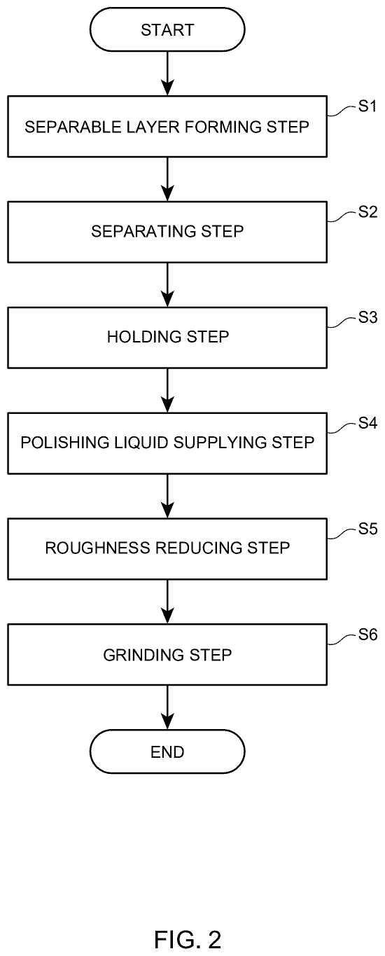

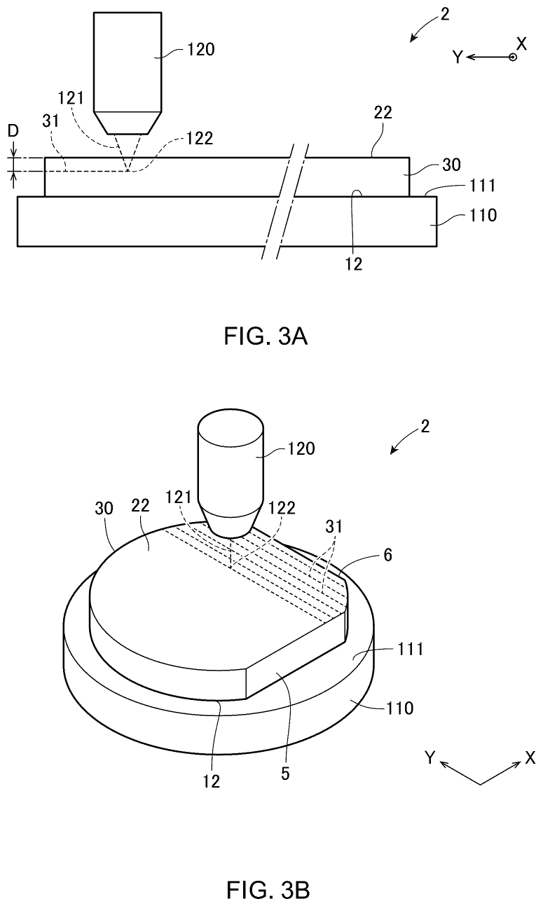

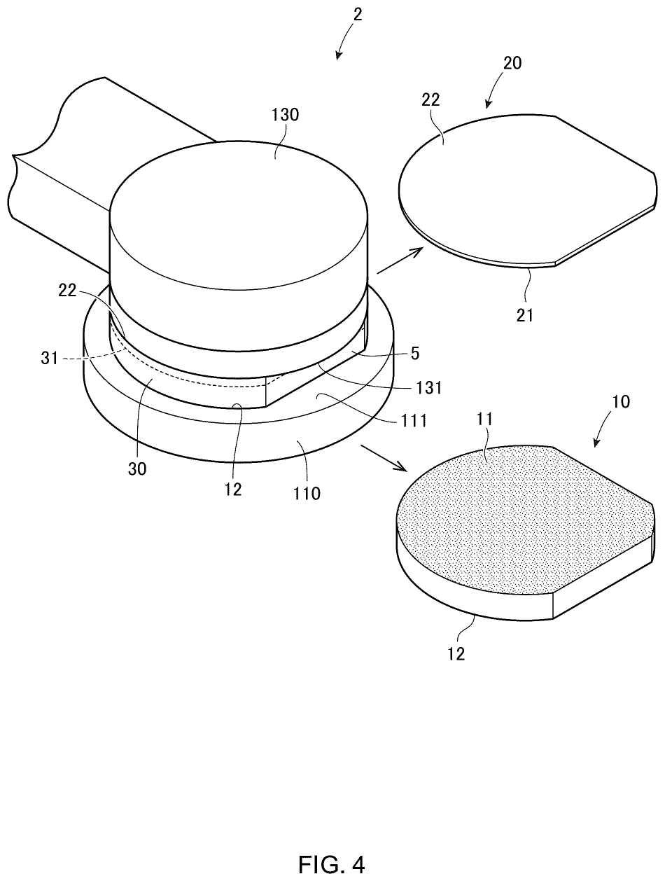

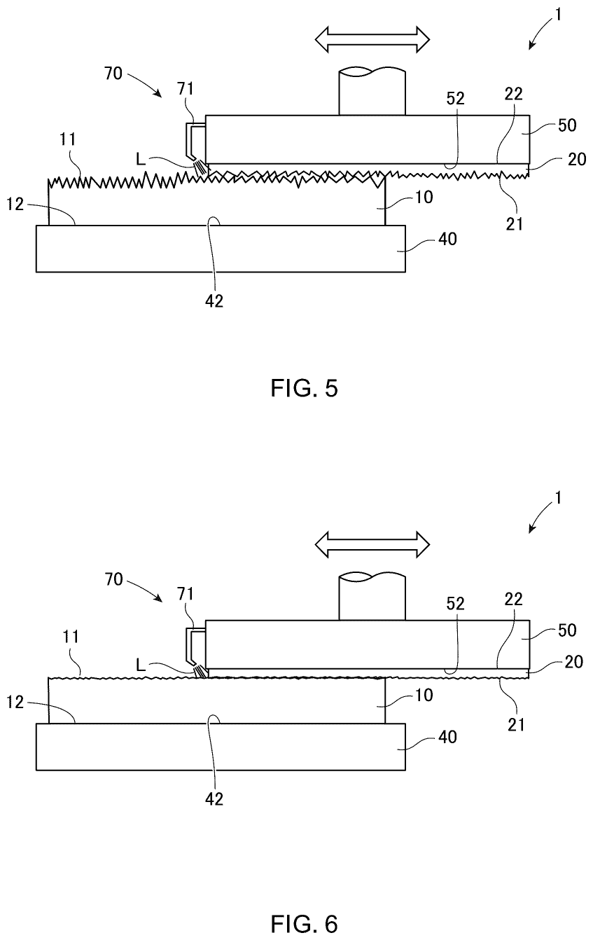

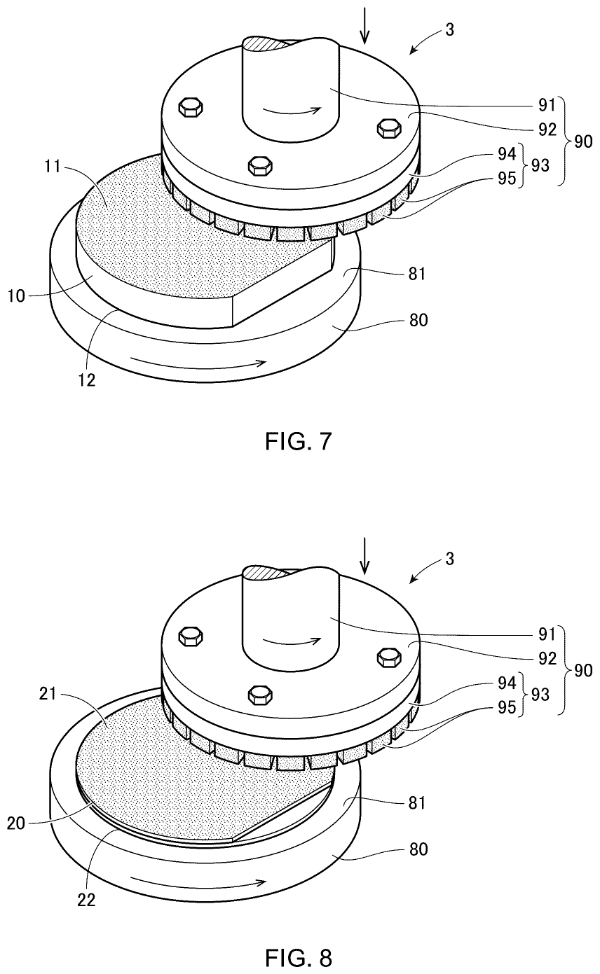

FIG. 2 is a flowchart of step included in the method for processing workpieces to be performed in the processing apparatus according to the first embodiment. FIGS. 3A-3B are a side view and a perspective view of a cutting apparatus to illustrate a separable layer forming step in the processing method according to the present embodiment. FIG. 4 is a perspective view of the cutting apparatus to illustrate a separating step in the processing method according to the present embodiment. FIG. 5 is a side view of the workpieces being in a state shortly after a roughness reducing step started in the processing method according to the present embodiment. FIG. 6 is a side view of the workpieces being in a state shortly before the roughness reducing step ends in the processing method according to the present embodiment. FIGS. 7 and 8 are perspective views of a grinding apparatus to illustrate a grinding step in the processing method according to the present embodiment. Hereinbelow, with reference to FIGS. 2-8, the method for processing the workpiece to be performed with the processing apparatus 1 will be described. In this exemplary case, the workpiece is made of SiC (silicon carbide), which is a typical hard material, the first workpiece s a SiC ingot, and the second workpiece is a SiC wafer.

The method for processing the workpieces according to the present embodiment includes, as shown in FIG. 2, a separable layer forming step (S1), a separating step (S2), a holding step (S3), a polishing liquid supplying step (S4), a roughness reducing step (S5), and a grinding step (S6), which will be described in this order below. Among these steps, steps S3 through S5 are performed by the processing apparatus 1 described above. Among the other steps, steps S1 and S2 are performed by a cutting apparatus 2, and step S6 is performed by a grinding apparatus 3.

### [Separable Layer Forming Step]

In the separable layer forming step, the cutting apparatus 2 forms a separable layer 31 in an ingot 30 being the SiC ingot by irradiating with a laser beam 121. More specifically, the cutting apparatus 2 may focus a laser beam, having a wavelength that may pass through the ingot 30 being the workpiece, at a position inside the ingot 30 and irradiate the ingot 30 with the laser beam to form a separable layer in the ingot 30. The cutting apparatus 2 may include, for example, as shown in FIGS. 3A-3B and 4, a chuck table 110 including a holder surface 111, a laser beam emitting unit 120, and a separating unit 130 including a holder surface 131. The laser beam emitting unit 120 is a pulse laser emitting unit configured to emit a pulsed laser beam having the wavelength that may pass through the ingot 30.

In the separable layer forming step, first, the cutting apparatus 2 suctions the surface 12 on one side of the ingot 30 and holds the ingot 30 against the holder surface 111 of the chuck table 110, as shown in FIGS. 3A and 3B. FIG. 3A illustrates the cutting apparatus 2 viewed from a side, and FIG. 3B is the cutting apparatus 2 viewed obliquely from an upper position. As shown in FIG. 3B, the chuck table 110 holds the ingot 30 in an orientation such that a first orientation flat 5 formed in the ingot 30 is aligned parallel to an X-axis direction, and a second orientation flat 6 formed in the ingot 30 is aligned parallel to a Y-axis direction. The X-axis direction and the Y-axis direction are horizontal and orthogonal to each other. The first orientation flat 5 and the second orientation flat 6, which is longer than the first orientation flat 5, are planes formed on a circumferential surface of the ingot 30 and intersect orthogonally with each other. The first orientation flat 5 coincides with a crystal orientation of the SiC.

Next, the cutting apparatus 2 moves the chuck table 110 and the laser beam emitting unit 120 relatively along the Y-axis direction, which is parallel to the second orientation flat 6, and emits a laser beam 121 from the laser beam emitting unit 120 focusing on a position at a predetermined depth D from the surface 22 of the ingot 30. Accordingly, focal points 122 are created along the Y-axis direction, and at each focal point 122, SiC is separated into Si and C, forming a modified region. Moreover, cracks extending from the focal points 122 along a C-plane of the SiC ingot parallel to the first orientation flat 5 cause a modified layer to expand, thereby forming a separable layer 31.

The modified region is an area where properties, such as density, refractive index, mechanical strength, and other physical characteristics, differ from those of the surrounding material. The modified region may include, for example, a melted region, a cracked region, a dielectric breakdown region, a refractive index change regions, and a region where these characteristics are mixed. The modified region has lower mechanical strength than the other parts of the ingot 30.

Furthermore, the cutting apparatus 2 temporarily stops emitting the laser beam from the laser beam emitting unit 120 and moves the chuck table 110 and the laser beam emitting unit 120 relatively by a predetermined distance along the X-axis direction, which is parallel to the first orientation flat 5. The cutting apparatus 2 there resumes emitting the laser beam 121 from the laser beam emitting unit 120 and moves the laser beam emitting unit 120 along the Y-axis direction, which is parallel to the second orientation flat 6, to focus the laser beam 121 on a position at the predetermined depth D from the surface 22 of the ingot 30 to form the separable layer 31. These processes are repeated to form the separable layer 31 at the predetermined depth D in the ingot 30 from the surface 22.

### [Separating Step]

In the separating step, the cutting apparatus 2 applies ultrasonic vibrations to the ingot 30, in which the separable layer 31 is formed, using the separating unit 130. Accordingly, the ingot 30 is split at the separable layer 31, and the part of the ingot 30 is separated as a plate-formed wafer.

In the separating step, first, the cutting apparatus 2 retracts the laser beam emitting unit 120 from the position above the ingot 30 and locates the separating unit 130 in place of the laser beam emitting unit 120 at the position above the ingot 30, as shown in FIG. 4. Next, the cutting apparatus 2 suctions the surface 22 of the ingot 30 being held by the chuck table 110 to hold the ingot 30 against the holder surface 131 of the separating unit 130. Further, the cutting apparatus 2 operates a liquid supplying device, which is not shown, to supply the liquid to a position between the separating unit 130 and the ingot 30 and applies alternating electric power to an ultrasonic vibrator in the separating unit 130 for a predetermined period to generate ultrasonic vibrations.

By causing ultrasonic vibration in the separating unit 130, the ultrasonic vibration is transmitted from the surface 22 into the ingot 30 to reach the separable layer 31. Accordingly, the ingot 30 is split at the separable layer 31, which is an origin point of the separation, and separated into a wafer, which is the workpiece 20 with a thickness corresponding to the depth D, and a remainder ingot, which is the workpiece 10. In other words, the wafer is separated from the ingot 30 at the separable layer 31 being the origin point of the separation. The separated workpieces 10 and 20 have surfaces, i.e., a surface 11 and a surface 21, respectively, which formed the separable layer 31 earlier. These surfaces (surface 11 and surface 12) have greater roughness compared to the opposite surfaces (surface 12 and surface 22).

In the example described above, the ultrasonic vibration is applied to the ingot 30 to separate the wafer. However, the separating method in the separating step is not necessarily limited as long as the ingot 30 is split at the separable layer 31 being the origin point. In other words, the ingot 30 may be split without using the ultrasonic vibration in the separating step.

### [Holding Step]

In the holding step, the processing apparatus 1 holds the workpiece 10 with the first holder device 40 and the workpiece 20, which is made of the same material as the workpiece 10, with the second holder device 50. Specifically, first, the processing apparatus 1 controls the motion unit 60 to lift the second holder device 50 to the retracted position. Next, the processing apparatus 1 suctions the surface 12 to hold the workpiece 10 against the holder surface 42 of the first holder device 40 and the surface 22 to hold the workpiece 20 against the holder surface 52 of the second holder device 50.

### [Polishing Liquid Supplying Step]

In the polishing liquid supplying step, the processing apparatus 1 supplies the polishing liquid L to the contact area between the workpiece 10 and the workpiece 20. Specifically, first, the processing apparatus 1 controls the motion unit 60 to move the second holder device 50 to the closer position, as shown in FIG. 5, so that the nozzle 71 of the polishing liquid supply unit 70 is located above the surface 11 of the workpiece 10 which is held by the first holder device 40. Further, the polishing liquid supply unit 70 supplies the polishing liquid L to the surface 11 through the nozzle 71. The polishing liquid L may spread over the surface 11 and flow into the area between the surface 11 and the surface 21, thereby supplying the polishing liquid L to the contact area between the workpiece 10 and the workpiece 20. The processing apparatus 1 continues supplying the polishing liquid L until the roughness reducing step, which will be described later, is completed.

### [Roughness Reducing Step]

In the roughness reducing step, the processing apparatus 1 moves the workpiece 10 and the workpiece 20 relatively while maintaining the workpiece 10 and the workpiece 20 in contact with each other, thereby reducing the roughness on the surfaces that contact each other. Specifically, first, the processing apparatus 1 controls the motion unit 60 to move the workpiece 10 and the workpiece 20 to contact each other. Further, the processing apparatus 1 moves the workpiece 20 relatively to the workpiece 10 using the motion unit 60 while maintaining the contact between the workpiece 10 and the workpiece 20. More specifically, the first motion unit 61 operates the first motion unit 61 to move the workpiece 20 to reciprocate in the horizontal direction while the second motion unit 63 adjusts the vertical position of the workpiece 20 so that the pressure values measured by the pressure sensors 64 are maintained at desired pressure values.

FIG. 5 shows of the workpieces 10, 20 in the state shortly after the roughness reducing step started, and FIG. 6 shows the workpieces 10, 20 shortly before the roughness reducing step ends. As shown in FIGS. 5 and 6, in the roughness reducing step, the surface 11 of the workpiece 10 and the surface 21 of the workpiece 20 abrade each other, and the roughness of the surface 11 and the roughness of the surface 21 are gradually reduced. Since the workpiece 10 and the workpiece 20 are made of the same material, without abrading solely one of the workpieces 10, 20 excessively, the roughness of both the surface 11 and the surface 21 may be reduced equally. Furthermore, by supplying the polishing liquid L from the polishing liquid supply unit 70 to the contact area between the workpiece 10 and the workpiece 20, protrusions in the roughness may be efficiently ground, thereby reducing the roughness of the surfaces 11, 20. For example, in a case where the polishing liquid L is the CMP slurry, chemical actions by the chemical components in the polishing liquid L and mechanical removal actions by the abrasive particles in the polishing liquid L may work simultaneously, and the roughness may be reduced efficiently.

### [Grinding Step]

In the grinding step, the grinding apparatus 3 grinds the surfaces (surface 11 and surface 21) being the processing targets, of which roughness has been reduced in the roughness reducing step. As shown in FIGS. 7 and 8, the grinding apparatus 3 includes a chuck table 80 with a holder surface 81 and a grinding unit 90. The grinding unit 90 includes a spindle 91, a mount 92 attached to a lower end of the spindle 91, and a grinding wheel 93 held on a lower surface of the mount 92. The grinding wheel 93 includes a wheel base 94 and a plurality of grindstones 95 arranged annularly on a lower surface of the wheel base 94.

In the grinding step, the grinding apparatus 3 grinds the workpiece 10 and the workpiece 20 in sequence. First, as shown in FIG. 7, the grinding apparatus 3 suctions the surface 12 to hold the workpiece 10 against the holder surface 81 of the chuck table 80. Further, while supplying a grinding liquid to the surface 11, the grinding apparatus 3 grinds the surface 11 with the grindstones 95. Specifically, the grinding wheel 93, which rotates around a central axis thereof along with the rotation of the spindle 91, is gradually moved closer to the rotating workpiece 10 at a predetermined speed. Accordingly, the grindstones 95 contact and grind the surface 11. Next, as shown in FIG. 8, the grinding apparatus 3 suctions the surface 22 to hold the workpiece 20 against the holder surface 81 of the chuck table 80. Thereafter, while supplying the grinding liquid to the surface 21, the grinding apparatus 3 grinds the surface 21 with the grindstones 95. Specifically, the grinding wheel 93, which rotates around the central axis thereof along with the rotation of the spindle 91, is gradually moved closer to the rotating workpiece 20 at the predetermined speed. Accordingly, the grindstones 95 contact and grind the surface 21. The grinding work with the workpiece 20 continues until the workpiece 20 is ground to a desired thickness.

As described above, according to the method for processing workpieces of the present embodiment, the processing apparatus 1 may cause the workpieces of the same material to abrade each other to reduce the roughness of the surfaces without abrading solely one of the workpieces excessively, and the roughness of both of the surfaces may be reduced equally. In particular, by supplying the polishing liquid to the contact area between these workpieces, the roughness of the surfaces may be efficiently reduced in a short period. Furthermore, according to the method for processing workpieces of the present embodiment, after reducing the roughness by rubbing the workpieces with each other in the processing apparatus 1, the grinding apparatus 3 grinds the workpieces. Thereby, compared to a case where the workpieces are ground without having the roughness reduced earlier, an amount of the grindstones 95 to be worn may be reduced. In particular, when the workpieces are made of a hard material such as SiC, the amount of the grindstones 95 to be worn may be largely reduced. Consequently, the workpieces may be processed more economically by lowering the processing costs. Moreover, as the processing apparatus 1 reduces the roughness by rubbing the workpieces of the same material with each other, there may be fewer restrictions on the material for the workpieces that may be processed, allowing various materials to be used to produce the workpieces.

In the present embodiment, an example, in which the polishing liquid supplying step starts before the roughness reducing step and continues until the roughness reducing step is completed, is presented. However, as long as sufficient polishing liquid L is supplied to the contact area during the roughness reducing step, timing and duration of the polishing liquid supplying step are not necessarily limited to this example. For example, the polishing liquid supplying step and the roughness reducing step may be performed in sequence and repeated in a way such that the polishing liquid supplying step is performed, thereafter the roughness reducing step is performed for a predetermined length of time and temporarily paused, the polishing liquid supplying step is performed, and after the polishing liquid supplying step ends, the roughness reducing step is resumed. In this arrangement, optionally, the polishing liquid supplying step may be performed with the surface 11 and the surface 21 being slightly separated to reserve a gap for the polishing liquid L to enter. For another example, the polishing liquid supplying step may be performed intermittently at regular or irregular intervals during the roughness reducing step.

In the present embodiment, an example, in which a single type of polishing liquid L is supplied to the contact area in the polishing liquid supplying step, is presented. However, two or more types of polishing liquids L may be supplied optionally. The polishing liquid L may be selected according to the material of the workpieces, or two or more types of polishing liquids L may be supplied during the polishing liquid supplying step to the same material. The plurality of types of polishing liquids L may include, for example, polishing liquids with different grinding efficiencies, or the polishing liquids L may be altered according to the progress of reducing the roughness during the polishing liquid supplying step. Furthermore, the plurality of polishing liquids L may include, for example, a polishing liquid emphasizing a cooling effect to the workpieces and a polishing liquid emphasizing grinding efficiency, and these polishing liquids may be switched from one to the other within the polishing liquid supplying step.

In the present embodiment, an example, in which the polishing liquid L used in the polishing liquid supplying step is a CMP slurry, is presented. However, the polishing liquid L is not necessarily limited to the CMP slurry as mentioned above, as long as the polishing liquid L promotes removal of the roughness. In other words, it is preferable that the polishing liquid L preferably contains abrasive particles so that the mechanical removal action of the abrasive particles is effective.

In the present embodiment, an example, in which the polishing liquid supply unit 70 supplies the polishing liquid L to the contact area through the nozzle 71 fixed to the second holder device 50, is presented. However, the location of the nozzle 71 is not necessarily limited as long as the polishing liquid supply unit 70 is enabled to supply the polishing liquid L to the contact area between the workpiece 10 and the workpiece 20. For example, the nozzle 71 may be fixed to the first holder device 40 or the mounting base 43. Moreover, in the present embodiment, an example, in which the single nozzle 71 supplies the polishing liquid L, is presented, but the number of nozzle 71 is not necessarily limited to one. For example, the polishing liquid supply unit 70 may have a plurality of nozzles 71, which may supply the polishing liquid L over a wider range in the contact area. Furthermore, the plurality of nozzles 71 may be provided on both sides of the second holder device 50 in the horizontal movable direction so that the polishing liquid L may be supplied to the contact area stably in either case where the second holder device 50 moves in one way or the other way along the horizontal direction.

In the present embodiment, an example of the method for processing workpieces including the separable layer forming step, the separating step, the holding step, the polishing liquid supplying step, the roughness reducing step, and the grinding step is presented. However, the method for processing workpieces does not necessarily consist of these six steps but may include more steps. For example, a cleaning step to wash the workpieces with water may be added after the roughness reducing step or after the grinding step. For another example, one or more of the steps in the method in the above example may be omitted. For example, if the workpieces are processed to substantially flat and thin forms in the roughness reducing step, the grinding step may be omitted. For another example, in a case where workpieces to be processed are prepared in advance, the separable layer forming step and the separating step may be omitted. In other words, the method for processing workpieces needs to include at least the holding step, the polishing liquid supplying step, and the roughness reducing step.

In the present embodiment, an example, in which the first workpiece is an ingot and the second workpiece is a wafer cut from the ingot, is presented. In other words, in the example, the first workpiece is an ingot having a surface separated from a wafer, and the second workpiece is the wafer having a surface separated from the ingot. However, as long as the workpieces are both made of the same material, the combination of the workpieces are not limited. For example, both the first workpiece and the second workpiece may be wafers cut from an ingot with separated surfaces, or both the first workpiece and the second workpiece may be ingots with separated surfaces. If at least one of the first workpiece or the second workpiece is a wafer, a wafer with reduced roughness is achievable through the method for processing workpieces according to the present disclosure. In other words, in the case where at least one of the first workpiece or the second workpiece is a wafer, the method for processing workpieces described above is applicable as a method for manufacturing wafers having reduced roughness or as a method for manufacturing wafers from workpieces, where a thickness of the manufactured wafer is smaller than a thickness of the workpieces.

### Second Embodiment

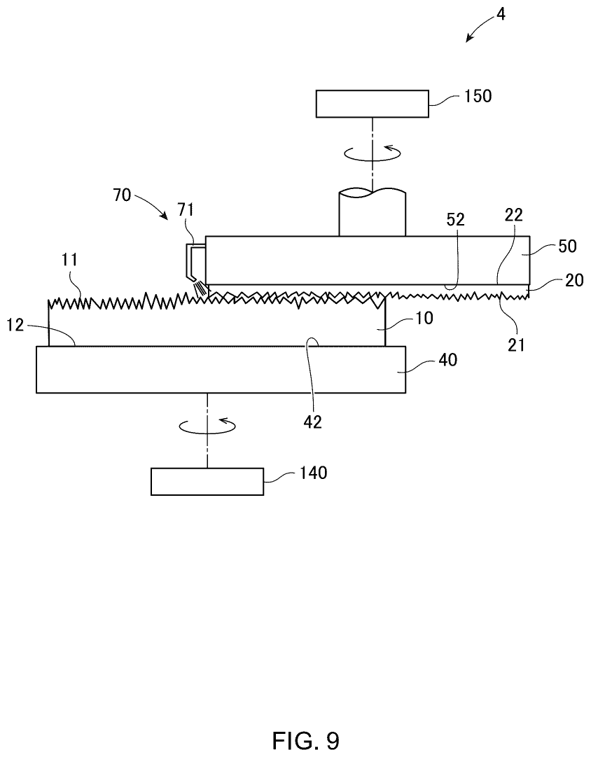

FIG. 9 is an illustrative side view of a processing apparatus 4 according to a second embodiment. The processing apparatus 4 shown in FIG. 9 may be used in the method for processing workpieces, as well as the processing apparatus 1 in the first embodiment. The processing apparatus 4 may differ from the processing apparatus 1 in the first embodiment in having a rotation driving source 140 and a rotation driving source 150 in place of the motion unit 60, but the remainder of the processing apparatus 4 is the same as that of the processing apparatus 1.

The rotation driving source 140 is a driving source to rotate the first holder device 40 on an axis that intersects orthogonally with the holder surface 42, and the first holder device 40 is configured to be rotated by a force of the rotation driving source 140. The rotation driving source 150 is a driving source to rotate the second holder device 50 on an axis that intersects orthogonally with the holder surface 52, and the second holder device 50 is configured to be rotated by a force of the rotation driving source 150.

The rotation driving source 140 and the rotation driving source 150 are motion mechanisms for rotating the first holder device 40 and the second holder device 50 to move the first holder device 40 and the second holder device 50 relatively. The configuration of the processing apparatus 4 is not necessarily limited as long as the processing apparatus 4 is provided with at least one of the rotation driving source 140 or the rotation driving source 150.

With the processing apparatus 4 configured as above, the method for processing workpieces described above may be performed as well. That is, the processing apparatus 4 supplies the polishing liquid L to the contact area between the workpiece 10 (first workpiece) and the workpiece 20 (second workpiece) using the polishing liquid supply unit 70, and by operating the rotation driving source 140 and the rotation driving source 150 to rotate the workpiece 10 and the workpiece 20, while maintaining the workpiece 10 and the workpiece 20 in contact with each other, the roughness of the contacting surfaces of the workpiece 10 and the workpiece 20 may be reduced.

With the processing apparatus 4 according to the present embodiment, as well as the processing apparatus 1, by rubbing the workpieces of the same material together, without abrading solely one of the workpieces excessively, and the roughness of the both surfaces may be reduced equally. In particular, by supplying the polishing liquid to the contact area between these workpieces, the roughness of the surfaces may be efficiently reduced in a short period. Furthermore, after reducing the roughness by rubbing the workpieces together in the processing apparatus 4, the grinding apparatus 3 grinds the workpieces, and thereby an amount of the grindstones 95 to be worn may be reduced, as well as the processing apparatus 1.

In the first and second embodiments described above, examples, in which the processing apparatus 1 and the processing apparatus 4 with the first holder device 40 and the second holder device 50 arranged such that the horizontal holder surfaces (the holder surface 42 and the holder surface 52) are held to face each other, are explained. However, arrangement of the first holder device 40 and the second holder device 50 is not necessarily limited to that in the examples, as long as the processing apparatus 1 or the processing apparatus 4 is enabled to hold the workpieces (the workpiece 10 and the workpiece 20) such that the surfaces (the surface 11 and the surface 21) being the processing targets are held to face each other. For example, the processing apparatus 1 or the processing apparatus 4 may have the first holder device 40 and the second holder device 50 that are in an arrangement such that the holder surfaces facing each other are tilted with respect to the horizontal direction by a predetermined angle. The predetermined angle is not necessarily limited but may be, for example, 90 degrees or a few degrees. In the case where the holder surfaces are tilted, the surfaces of the workpieces being the processing targets are tilted as well. Therefore, it is preferable that the nozzle 71 of the polishing liquid supply unit 70 is located at a position such that the polishing liquid L is poured to an area higher than the contact area between the surfaces being the processing targets. This configuration is advantageous in that the polishing liquid L may be efficiently guided to the contact area using the inclination of the surfaces being the processing targets.

### Third Embodiment

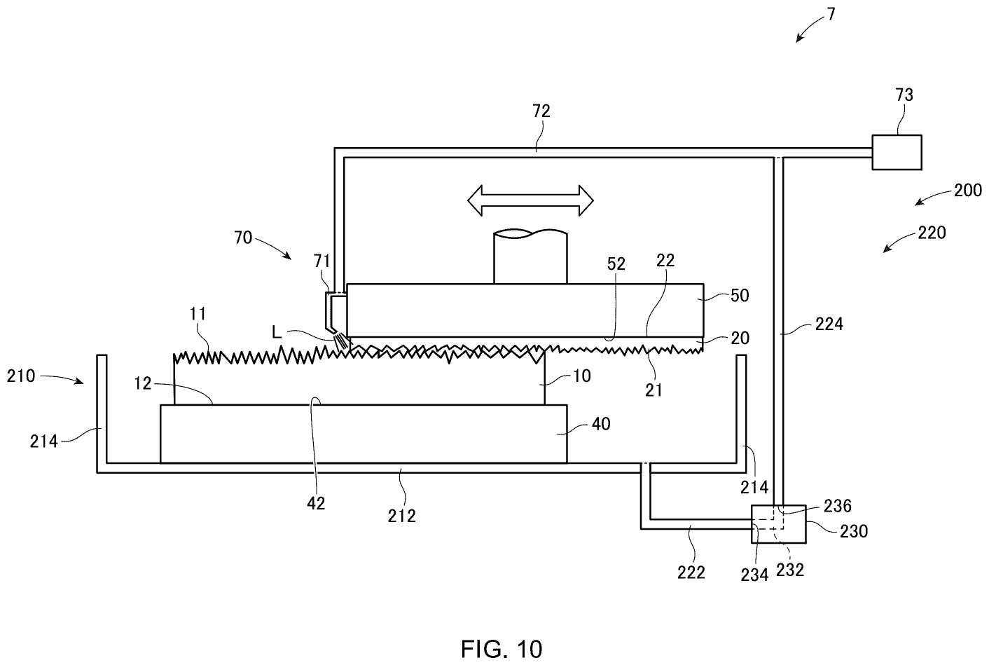

FIG. 10 is an illustrative view of a processing apparatus 7 according to a third embodiment. The processing apparatus 7 shown in FIG. 10 may be used in the method for processing workpieces, as well as the processing apparatus 1 in the first embodiment. The processing apparatus 7 shown in FIG. 10 may differ from the processing apparatus 1 in the first embodiment in having a debris utilizing unit 200, but the remainder of the processing apparatus 7 is the same as that of the processing apparatus 1.

The debris utilizing unit 200 may collect waste liquid resulted from reduction of the roughness and use debris from the workpiece 10 or the workpiece 20 that is contained in the collected waste liquid as abrasives in the polishing liquid L. As shown in FIG. 10, the debris utilizing unit 200 includes a collecting device 210 for collecting the waste liquid, a recycle flow path 220 connecting the collecting device 210 to the polishing liquid supply unit 70, and a pump 230 creating a flow of the fluid from the collecting device 210 to the polishing liquid supply unit 70 through the recycle flow path 220.

The collecting device 210 is a container for collecting the polishing liquid L flown out from the area between workpiece 10 and the workpiece 20. The collecting device 210 includes a bottom surface 212 and sidewalls 214. The bottom surface 212 is attached to a lower part of the first holder device 40, and the sidewalls 214 extend upward from edges of the bottom surface 212. The collecting device 210 configured as above may guide the debris from the workpiece 10 and the workpiece 20 along with the polishing liquid L to the recycle flow path 220 to collect the waste liquid containing the debris. The waste liquid collected in the collecting device 210 is guided to the polishing liquid supply unit 70 by the pump 230. More specifically, the pump 230 generates negative pressure on a side of a suction port 234, which includes a flow path 222, and positive pressure on a side of a discharge port 236, which includes a flow path 224, and creates a flow of fluid from the collecting device 210 toward the polishing liquid supply unit 70 by drawing the fluid into the flow path 232 through the suction port 234 and forwarding the fluid through the flow path 232 to the discharge port 236. With the flow of the fluid, the pump 230 may guide the waste liquid collected by the collecting device 210 to the supply path 72, which extends from the polishing liquid supply source 73 to the nozzle 71. Accordingly, a mixture liquid mixing the waste liquid and the CMP slurry supplied from the polishing liquid supply source 73 is supplied as the polishing liquid L to the contact area through nozzle 71. In this configuration, the nozzle 71, the supply path 72, and polishing liquid supply source 73 compose the polishing liquid supply unit 70.

In the processing apparatus 7 configured as above, by operating the pump 230 during the roughness reducing step and the polishing liquid supplying step, the waste liquid may be recycled as the polishing liquid L. In other words, a debris utilizing step, in which the debris generated from the workpiece 10 or the workpiece 20 and contained in the waste liquid may be used in the polishing liquid L, is performed.

The interaction between the debris contained in the polishing liquid L and the surface 11 of workpiece 10 or the surface 21 of workpiece 20 during the roughness reducing step is expected to have a similar effect to the mutual abrasion between surface 11 or the workpiece 10 and the surface 21 of the workpiece 20. This is because the debris contained in the polishing liquid L originates from workpieces 10 and 20 and is made of the same material, and the polishing liquid L including the waste liquid may exhibit the effect to reduce the roughness similarly to the polishing liquid made of pure CMP slurry. Therefore, according to the processing apparatus 7 of the present embodiment, while conserving the CMP slurry by recycling the waste liquid, the polishing liquid L may reduce the roughness highly effectively.

In the above description, examples, in which the polishing liquid supply source 73 supplies the CMP slurry, are presented. However, optionally, the polishing liquid supply source 73 may switch the liquid to supply between the CMP slurry and water. For example, the polishing liquid supply source 73 may supply the CMP slurry for a predetermined period from the start of the roughness reducing step and thereafter may be switched to supply water. By supplying the CMP slurry during the initial period when the amount of debris contained in the waste liquid is relatively small, the roughness may be effectively reduced with the polishing liquid L. On the other hand, after a certain period, when the waste liquid contains a sufficient amount of debris, consumption of the CMP slurry may be reduced while the effect of reducing roughness may be ensured with the debris. As such, without lowering the processing performance of the processing apparatus 7 excessively, an amount of the CMP slurry to be consumed may be reduced. On the other hand, optionally, the polishing liquid supply source 73 may supply water from the beginning of the roughness reducing step to further minimize consumption of the CMP slurry.

In the above description, an example, in which the collected waste liquid is recycled as the polishing liquid, is presented. Meanwhile, the debris utilizing unit 200 may be any unit that is capable of using debris of the workpiece 10 or the workpiece 20 contained in the waste liquid for the polishing liquid L. Optionally, for example, the debris may be extracted from the waste liquid, which is collected in the collecting device 210, with, for example a filter, and the extracted debris may be provided to the supply path 72. For another example, a particle size of the extracted debris may be selected optionally, and the debris sorted by the particle size may be provided to the supply path 72 and used as the polishing liquid L. In these cases, the fluid supplied from the polishing liquid supply source 73 to the supply path 72 may not necessarily be limited but may be, for example, CMP slurry, water, or another liquid.

In the above description, an example, in which the collected waste liquid is immediately recycled as the polishing liquid L, is presented. However, the waste liquid may not necessarily be recycled immediately, but the debris extracted from previously collected waste liquid may be used as the polishing liquid L at a later time when needed. For example, the debris collected while reducing the roughness of some wafers may be used for reducing roughness of another wafers.

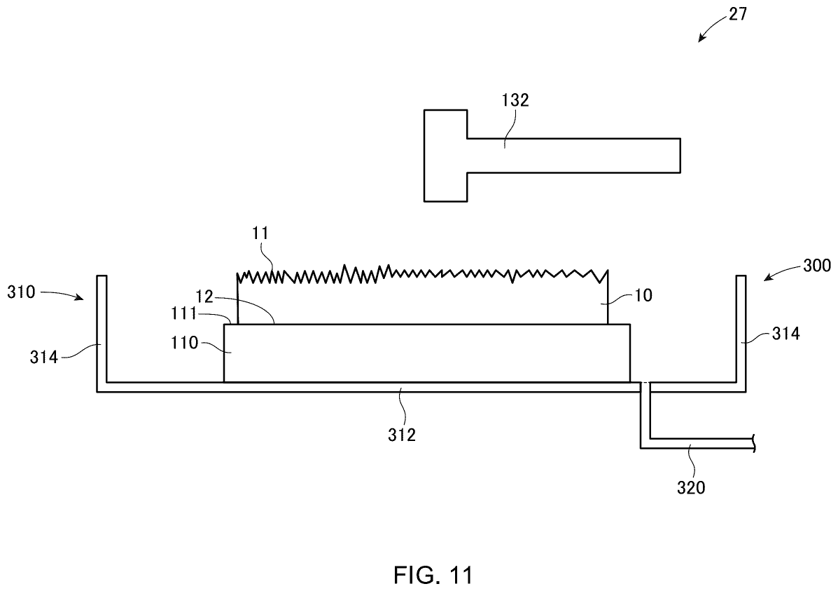

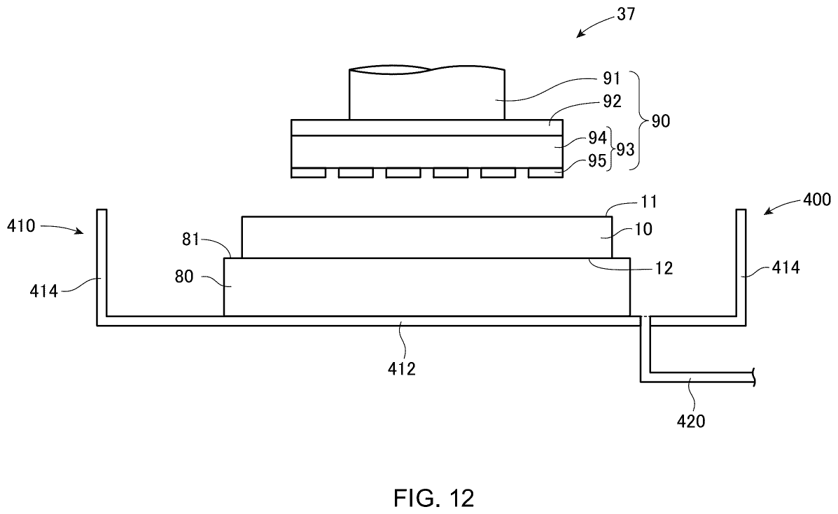

In the above description, an example, in which the debris generated during the roughness reducing step is recycled within the same step, is presented. However, the debris that is recycled in the roughness reducing step is not necessarily limited to the debris generated within the same step. Debris generated in a different step may be recycled as well in the roughness reducing step. For example, as shown in FIG. 11, debris generated in the separating step may be used in the polishing liquid L. More specifically, waste liquid, generated in a washing process in the separating step where a wafer is separated from an ingot, may be collected, and the debris contained in the waste liquid may be used as abrasives in the polishing liquid L in the roughness reducing step. FIG. 11 illustrates debris being generated from an ingot or a wafer when being separated, collected by a collecting device 310 along with a washing liquid supplied from a washing unit 132, and directed into a recycle flow path 320. For another example, as shown in FIG. 12, debris generated in the grinding step may be used in the roughness reducing step as well. More specifically, a grinding liquid used in the grinding step may be collected, and debris contained in the collected waste liquid may be used in the roughness reducing step. FIG. 12 illustrates the grinding debris generated in the grinding step being collected by a collecting device 410 along with the grinding liquid supplied from the grinding unit 90 and directed into a recycle flow path 420. A cutting apparatus 27 shown in FIG. 11 has the same configuration as the cutting apparatus 2 shown in FIG. 4 but is different from the cutting apparatus 2 in having a debris utilizing unit 300. Similarly, a grinding apparatus 37 shown in FIG. 12 has the same configuration as the grinding apparatus 3 shown in FIGS. 7 and 8 but is different from the grinding apparatus 3 in having a debris utilizing unit 400. Meanwhile, the debris utilizing unit 300 shown in FIG. 11 and the debris utilizing unit 400 shown in FIG. 12 have the same configuration as the debris utilizing unit 200 shown in FIG. 10.

In the above description, examples, in which the debris generated from the workpieces is recycled in the roughness reducing step, are presented. However, the debris may be used in other steps as well. For example, the debris may be used in the grinding step. However, in the grinding step, it is preferable to use debris with a small particle size to prevent damage to the grinding surface.

In the above description, an example, in which the collected waste liquid is directed to the polishing liquid supply unit 70 by the collecting device 210, is presented. However, if the polishing liquid supply source 73 is enabled to convey the collected debris to the polishing liquid supply unit 70 without a pump, the debris utilizing unit 200 may omit the pump 230.

Embodiments of the present disclosure may not necessarily be limited to the configurations described above or in the modified example but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure.

The above embodiments used SiC as an example of the material for the first workpiece and the second workpiece. However, materials for the workpieces are not limited to SiC. For example, the workpieces may be made of Ge (germanium), GaAs (gallium arsenide), or Si (silicon).

As described above, the method for processing workpieces, the processing apparatus, and the method for manufacturing a wafer according to the present disclosure may effectively reduce roughness of the workpieces, even when the workpieces are made of a hard material such as SiC, and are advantageous in industrial fields including semiconductor wafer manufacturing.

What is claimed is:

1. A method for processing workpieces, comprising:
holding a first workpiece on a first holder device and holding a second workpiece made of a same material as the first workpiece on a second holder device;
reducing roughness of the first workpiece and the second workpiece including moving the first workpiece and the second workpiece relatively while the first workpiece and the second workpiece are maintained in contact with each other to reduce roughness on contacting surfaces of the first workpiece and the second workpiece that contact each other; and
supplying a polishing liquid to a contact area between the first workpiece and the second workpiece.

2. The method according to claim 1, wherein the first workpiece and the second workpiece are each either an ingot having a separated surface, from which a wafer is separated, or a wafer having a separated surface separated from an ingot.

3. The method according to claim 1, further comprising utilizing debris generated from the first workpiece or the second workpiece in the polishing liquid.

4. The method according to claim 3, wherein, in utilizing debris, debris generated from the first workpiece or the second workpiece in reducing roughness is utilized in the polishing liquid.

5. The method according to claim 2, further comprising:
separating the wafer from the ingot; and
utilizing debris in the polishing liquid, the debris being separation debris generated from the ingot or the wafer when separating the wafer from the ingot.

6. A processing apparatus, comprising:
a first holder device configured to hold a first workpiece;
a second holder device configured to hold a second workpiece made of a same material as the first workpiece in an arrangement such that the second workpiece faces the first workpiece held on the first holder device;
a motion device configured to move the first holder device and the second holder device relatively; and
a polishing liquid supply unit configured to supply a polishing liquid to a contact area between the first workpiece and the second workpiece,
wherein the processing apparatus is configured to reduce roughness on surfaces of the first workpiece and the second workpiece that contact each other by:
operating the polishing liquid supply unit to supply the polishing liquid to the contact area between the first workpiece and the second workpiece, and
operating the motion device to move the first workpiece held on the first holder and the second workpiece held on the second holder device relatively while the first workpiece and the second workpiece are maintained in contact with each other.

7. The processing apparatus according to claim 6, further comprising a debris utilizing unit configured to collect a waste liquid generated when reducing the roughness and utilize debris from the first workpiece or the second workpiece contained in the collected waste liquid in the polishing liquid.

8. A method for manufacturing a wafer from at least one of a first workpiece or a second workpiece made of a same material as the first workpiece, comprising:
holding the first workpiece on a first holder device and holding the second workpiece on a second holder device;
reducing roughness of the first workpiece and the second workpiece including moving the first workpiece and the second workpiece relatively while the first workpiece and the second workpiece are maintained in contact with each other to reduce roughness on contacting surfaces of the first workpiece and the second workpiece that contact each other; and
supplying a polishing liquid to a contact area between the first workpiece and the second workpiece.

9. A method for manufacturing a wafer from a workpiece, the wafer having a smaller thickness than the workpiece, comprising:
forming a separable layer including emitting a laser beam having a wavelength to pass through the workpiece focused at a position inside the workpiece to form the separable layer in the workpiece;
separating a first workpiece from the workpiece at the separable layer being an origin point of separation;
reducing roughness of the first workpiece and a second workpiece being a remainder of the workpiece, from which the first workpiece is separated, including moving the first workpiece and the second workpiece relatively while the first workpiece and the second workpiece are maintained in contact with each other, to reduce roughness on contacting surfaces of the first workpiece and the second workpiece that contact each other;
supplying a polishing liquid to a contact area between the first workpiece and the second workpiece; and
utilizing debris in the polishing liquid, the debris being separation debris generated from the first workpiece or the second workpiece in separating the first workpiece from the workpiece or being generated from the first workpiece or the second workpiece in reducing roughness of the first workpiece and the second workpiece.
